(19) United States
(12) Patent Application Publication
(10) Pub. No.: US 2021/0222882 A1
(43) Pub. Date: Jul. 22, 2021

(54) THERMALLY POWERED FAN ASSEMBLY

(71) Applicant: Dustin Johnson, Woodland Park, CO (US)

(72) Inventor: Dustin Johnson, Woodland Park, CO (US)

(21) Appl. No.: 16/747,201

(22) Filed: Jan. 20, 2020

(51) Int. Cl. F24B 1/189; F04D 3/00; F04D 7/00; H01L 35/30; H02K 7/14; F04D 13/06

(52) U.S. Cl. CPC F24B 1/189; F04D 3/005; F04D 13/06; H01L 35/30; H02K 7/14; F04D 7/00

(57) ABSTRACT

A thermally powered fan assembly for blowing heated air from a fireplace includes a screen that is positionable in front of a fireplace. A blower is coupled to the screen and the blower urging air through the screen when the blower is turned on. In this way the blower urges heated air outwardly from the fireplace to enhance heating an area. A thermoelectric power supply is coupled to the screen wherein the thermoelectric power and the thermoelectric power supply produces an electrical current when the thermoelectric power supply is exposed to a thermal gradient. It this way the thermoelectric power supply converts heat from the fireplace into electrical current. The blower is electrically coupled to the thermoelectric power supply.

### CROSS-REFERENCE TO RELATED APPLICATIONS

Not Applicable

### STATEMENT REGARDING FEDERALLY SPONSORED RESEARCH OR DEVELOPMENT

Not Applicable

### THE NAMES OF THE PARTIES TO A JOINT RESEARCH AGREEMENT

Not Applicable

### INCORPORATION-BY-REFERENCE OF MATERIAL SUBMITTED ON A COMPACT DISC OR AS A TEXT FILE VIA THE OFFICE ELECTRONIC FILING SYSTEM

Not Applicable

### STATEMENT REGARDING PRIOR DISCLOSURES BY THE INVENTOR OR JOINT INVENTOR

Not Applicable

### BACKGROUND OF THE INVENTION

### (1) Field of the Invention

The disclosure relates to thermal fan device and more particularly pertains to a new thermal fan device for blowing heated air from a fireplace.

### (2) Description of Related Art Including Information Disclosed Under 37 CFR 1.97 and 1.98

The prior art relates to thermal fan device.

### BRIEF SUMMARY OF THE INVENTION

An embodiment of the disclosure meets the needs presented above by generally comprising a screen that is positionable in front of a fireplace. A blower is coupled to the screen and the blower urging air through the screen when the blower is turned on. In this way the blower urges heated air outwardly from the fireplace to enhance heating an area. A thermoelectric power supply is coupled to the screen wherein the thermoelectric power and the thermoelectric power supply produces an electrical current when the thermoelectric power supply is exposed to a thermal gradient. It this way the thermoelectric power supply converts heat from the fireplace into electrical current. The blower is electrically coupled to the thermoelectric power supply.

There has thus been outlined, rather broadly, the more important features of the disclosure in order that the detailed description thereof that follows may be better understood, and in order that the present contribution to the art may be better appreciated. There are additional features of the disclosure that will be described hereinafter and which will form the subject matter of the claims appended hereto.

The objects of the disclosure, along with the various features of novelty which characterize the disclosure, are pointed out with particularity in the claims annexed to and forming a part of this disclosure.

### BRIEF DESCRIPTION OF SEVERAL VIEWS OF THE DRAWING(S)

The disclosure will be better understood and objects other than those set forth above will become apparent when consideration is given to the following detailed description thereof. Such description makes reference to the annexed drawings wherein:

FIG. 1 is a front view of a thermally powered fan assembly according to an embodiment of the disclosure.

FIG. 2 is a top view of an embodiment of the disclosure.

FIG. 3 is a detail view taken from circle 3 of FIG. 2 of an embodiment of the disclosure.

FIG. 4 is an exploded perspective view of an embodiment of the disclosure.

FIG. 5 is a schematic view of an embodiment of the disclosure.

### DETAILED DESCRIPTION OF THE INVENTION

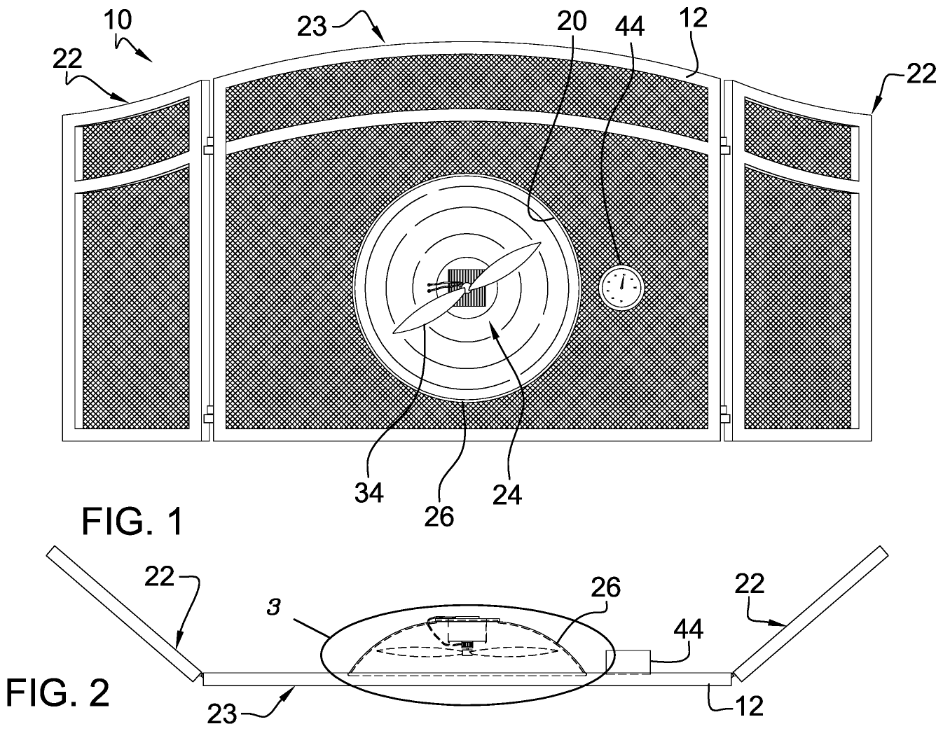

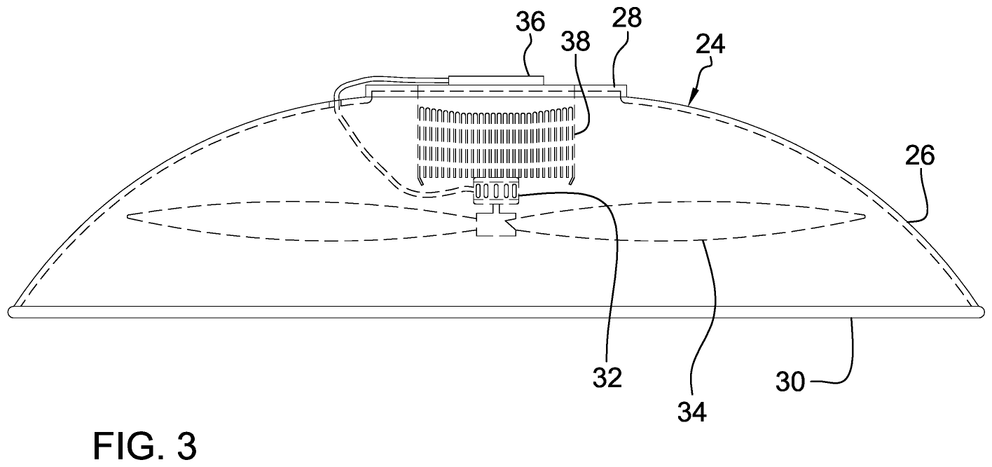

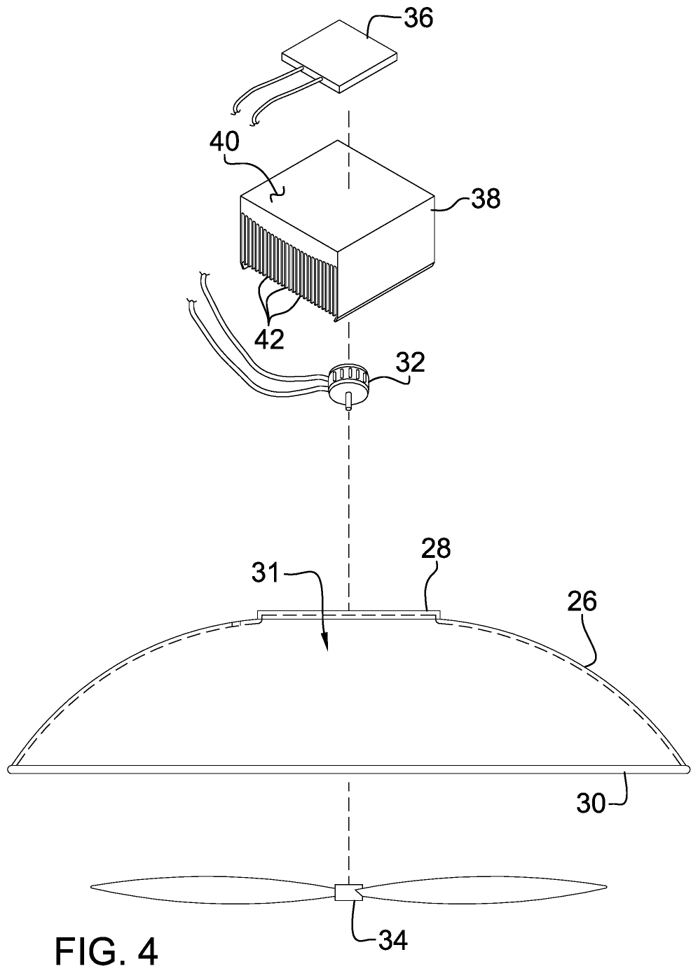

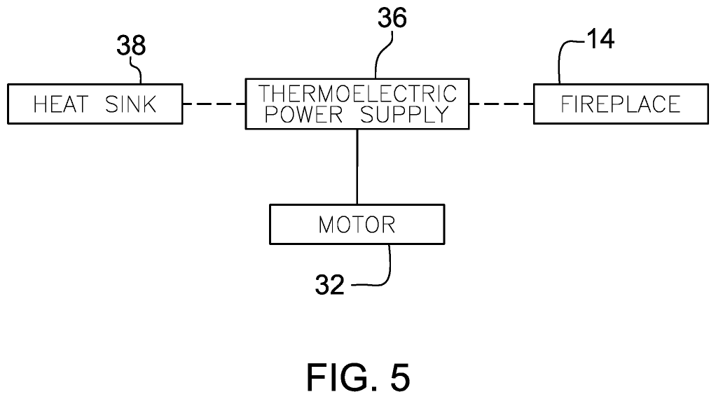

With reference now to the drawings, and in particular to FIGS. 1 through 5 thereof, a new thermal fan device embodying the principles and concepts of an embodiment of the disclosure and generally designated by the reference numeral 10 will be described.

As best illustrated in FIGS. 1 through 5, the thermally powered fan assembly 10 generally comprises a screen 12 that is positionable in front of a fireplace 14 to inhibit flaming material from escaping the fireplace 14. The screen 12 is comprised of a thermally resistant material, such as steel or the like, to resist heat from the fireplace 14. The screen 12 has a front surface 16 and a back surface 18, the screen 12 has a hole 20 extending through the front surface 16 and the back surface 18, and the hole 20 is centrally positioned on the screen 12. As is most clearly shown in FIGS. 1 and 2, the screen 12 may comprise a pair of wing portions 22 being hingedly coupled to a central portion 23. The fireplace 14 may be a wood burning fireplace 14, a wood burning stove or any other type of heat source that burns a combustible material to produce heat.

A blower 24 is coupled to the screen 12 such that the blower 24 is in fluid communication with an interior of the fireplace 14. The blower 24 urges air through the screen 12 when the blower 24 is turned on to urge heated air outwardly from the fireplace 14. In this way the blower 24 enhances heating an area. The blower 24 comprises a dish 26 that is comprised of a fluid impermeable material to inhibit air from passing therethrough. Additionally, the dish 26 is comprised of a thermally conductive material such that the dish 26 is in thermal communication with ambient air.

The dish 26 has a bottom wall 28 and a top edge 30, and the top edge 30 is coupled to the screen 12 having the dish 26 being aligned with the hole 20 in the screen 12. The dish 26 extends away from the back surface 18 of the screen 12 such that the dish 26 is in thermal communication with the fireplace 14 when the screen 12 is positioned therearound. Additionally, the bottom wall 28 has an opening 31 extending therethrough.

The blower 24 includes a motor 32 that is mounted in the dish 26. The motor 32 rotates in a first direction when the motor 32 is turned on and the motor 32 may comprise an electric motor 32 or the like. The blower 24 includes a fan 34 that is coupled to an output shaft of the motor 32. The motor 32 rotates the fan 34 when the motor 32 is turned on to urge air from the fireplace 14 into the area being heated.

A thermoelectric power supply 36 is coupled to the screen 12 and the thermoelectric power supply 36 is in thermal communication with the fireplace 14 when the screen 12 is positioned therearound. Moreover, the thermoelectric power supply 36 produces an electrical current when the thermoelectric power supply 36 is exposed to a thermal gradient. In this way the thermoelectric power supply 36 converts heat from the fireplace 14 into electrical current. The blower 24 is electrically coupled to the thermoelectric power supply 36. Additionally, the thermoelectric power supply 36 may comprise a Peltier device or the like.

A heat sink 38 is included that has a basal surface 40 and a plurality of fins 42. The heat sink 38 is coupled to the screen 12 having the basal surface 40 being positioned in the hole 20 in the dish 26. In this way the heat sink 38 is in thermal communication with ambient air in the area being heated. The thermoelectric power supply 36 is coupled to the basal surface 40 such that the thermoelectric power supply 36 is in thermal communication with the heat sink 38. Thus, the heat sink 38 communicates the temperature gradient to the thermoelectric power supply 36 when the thermoelectric power supply 36 is exposed to heat produced by the fireplace 14. Additionally, the motor 32 is removably attached to the fins 42 on the heat sink 38. A thermometer 44 is coupled to the screen 12 such that the thermometer 44 is in thermal communication with the fireplace 14. In this way the thermometer 44 can display the temperature of the fireplace 14.

In use, the screen 12 is positioned around the fireplace 14 when a fire is burning in the fireplace 14. In this way the thermoelectric power supply 36 is exposed to heat produced by the fire. Additionally, the thermoelectric power supply 36 is in thermal communication with the heat sink 38. Thus, the thermoelectric power supply 36 converts heat from the fire into electrical current to power the motor 32. In this way the fan 34 blows heated air to enhance heating the area without the need for batteries or a power cord.

With respect to the above description then, it is to be realized that the optimum dimensional relationships for the parts of an embodiment enabled by the disclosure, to include variations in size, materials, shape, form, function and manner of operation, assembly and use, are deemed readily apparent and obvious to one skilled in the art, and all equivalent relationships to those illustrated in the drawings and described in the specification are intended to be encompassed by an embodiment of the disclosure.

Therefore, the foregoing is considered as illustrative only of the principles of the disclosure. Further, since numerous modifications and changes will readily occur to those skilled in the art, it is not desired to limit the disclosure to the exact construction and operation shown and described, and accordingly, all suitable modifications and equivalents may be resorted to, falling within the scope of the disclosure. In this patent document, the word “comprising” is used in its non-limiting sense to mean that items following the word are included, but items not specifically mentioned are not excluded. A reference to an element by the indefinite article “a” does not exclude the possibility that more than one of the element is present, unless the context clearly requires that there be only one of the elements.

I claim:

1. A thermally powered fan assembly being configured to blow heated air outward from a heat source without consuming electrical energy, said assembly comprising:
a screen being positionable in front of a fireplace wherein said screen is configured to inhibit flaming material from escaping the fireplace, said screen being comprised of a thermally resistant material wherein said screen is configured to resist heat from the fireplace;
a blower being coupled to said screen wherein said blower is configured to be in fluid communication with an interior of the fireplace, said blower urging air through said screen when said blower is turned on wherein said blower is configured to urge heated air outwardly from the fireplace to enhance heating an area; and
a thermoelectric power supply being coupled to said screen wherein said thermoelectric power supply is configured to be in thermal communication with the fireplace when said screen is positioned therearound, said thermoelectric power supply producing an electrical current when said thermoelectric power supply is exposed to a thermal gradient wherein said thermoelectric power supply is configured to convert heat from the fireplace into electrical current, said blower being electrically coupled to said thermoelectric power supply.

2. The assembly according to claim 1, wherein said screen has a front surface and a back surface, said screen having a hole extending through said front surface and said back surface, said hole being centrally positioned on said screen.

3. The assembly according to claim 2, wherein said blower comprises a dish being mounted to said screen, said dish being aligned with said hole in said screen.

4. The assembly according to claim 3, wherein said dish is comprised of a fluid impermeable material to inhibit air from passing therethrough, said dish being comprised of a thermally conductive material wherein said dish is configured to be in thermal communication with ambient air.

5. The assembly according to claim 3, wherein said dish has a bottom wall and a top edge, said top edge being coupled to said screen having said dish being aligned with said hole in said screen, said dish extending away from said back surface of said screen wherein said dish is configured to be in thermal communication with the fireplace when said screen is positioned therearound, said bottom wall having an opening extending therethrough.

6. The assembly according to claim 5, wherein said blower comprises a motor being mounted in said dish, said motor rotating in a first direction when said motor is turned on.

7. The assembly according to claim 8, wherein said blower comprises a fan being coupled to an output shaft of said motor, said motor rotating said fan when said motor is turned on wherein said fan is configured to urge air from the fireplace into the area being heated.

8. The assembly according to claim 5, further comprising a heat sink having a basal surface and a plurality of fins, said heat sink being coupled to said screen having said basal surface being positioned in said hole in said dish wherein said heat sink is configured to be in thermal communication with ambient air in the area being heated.

9. The assembly according to claim 8, wherein said thermoelectric power supply is coupled to said basal surface such that said thermoelectric power supply is in thermal communication with said heat sink wherein said heat sink is configured to communicate the temperature gradient to said thermoelectric power supply when said thermoelectric power supply is exposed to heat produced by the fireplace.

10. A thermally powered fan assembly being configured to blow heated air outward from a heat source without consuming electrical energy, said assembly comprising:
a screen being positionable in front of a fireplace wherein said screen is configured to inhibit flaming material from escaping the fireplace, said screen being comprised of a thermally resistant material wherein said screen is configured to resist heat from the fireplace, said screen having a front surface and a back surface, said screen having a hole extending through said front surface and said back surface, said hole being centrally positioned on said screen;
a blower being coupled to said screen wherein said blower is configured to be in fluid communication with an interior of the fireplace, said blower urging air through said screen when said blower is turned on wherein said blower is configured to urge heated air outwardly from the fireplace to enhance heating an area, said blower comprising:
a dish being comprised of a fluid impermeable material to inhibit air from passing therethrough, said dish being comprised of a thermally conductive material wherein said dish is configured to be in thermal communication with ambient air, said dish having a bottom wall and a top edge, said top edge being coupled to said screen having said dish being aligned with said hole in said screen, said dish extending away from said back surface of said screen wherein said dish is configured to be in thermal communication with the fireplace when said screen is positioned therearound, said bottom wall having an opening extending therethrough;
a motor being mounted in said dish, said motor rotating in a first direction when said motor is turned on; and
a fan being coupled to an output shaft of said motor, said motor rotating said fan when said motor is turned on wherein said fan is configured to urge air from the fireplace into the area being heated; and
a thermoelectric power supply being coupled to said screen wherein said thermoelectric power supply is configured to be in thermal communication with the fireplace when said screen is positioned therearound, said thermoelectric power supply producing an electrical current when said thermoelectric power supply is exposed to a thermal gradient wherein said thermoelectric power supply is configured to convert heat from the fireplace into electrical current, said blower being electrically coupled to said thermoelectric power supply; and
a heat sink having a basal surface and a plurality of fins, said heat sink being coupled to said screen having said basal surface being positioned in said hole in said dish wherein said heat sink is configured to be in thermal communication with ambient air in the area being heated, said thermoelectric power supply being coupled to said basal surface such that said thermoelectric power supply is in thermal communication with said heat sink wherein said heat sink is configured to communicate the temperature gradient to said thermoelectric power supply when said thermoelectric power supply is exposed to heat produced by the fireplace, said motor being removably attached to said fins on said heat sink.
